(19) United States
(12) Patent Application Publication
(10) Pub. No.: US 2012/0132617 A1
(43) Pub. Date: May 31, 2012

(54) PLASMA ETCHING APPARATUS AND PLASMA ETCHING METHOD

(75) Inventor: Daisuke MATSUSHIMA, Yokohama-shi (JP)

(73) Assignee: SHIBAURA MECHATRONICS CORPORATION, Yokohama-shi (JP)

(21) Appl. No.: 13/389,181

(22) PCT Filed: Aug. 5, 2010
(86) PCT No.: PCT/JP2010/063306

§ 371 Date: Feb. 6, 2012

(30) Foreign Application Priority Data
Aug. 6, 2009 (JP) 2009-183600

(51) Int. Cl. H01L 21/3065

(52) U.S. Cl. 216/60; 156/345.25

(57) ABSTRACT

A plasma etching apparatus includes a processing container, a depressurization unit, a placement unit, a discharge tube, an introduction waveguide tube, a gas supply unit, a transport tube, a detection window, a coherent light detection unit, and a control unit. The control unit is configured to detect an end point of etching based on an output from the coherent light detection unit. The control unit is configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

### TECHNICAL FIELD

This invention relates to a plasma etching apparatus and etching method.

### BACKGROUND ART

Etching that utilizes plasma is practically used in a wide range of technical fields such as the manufacture of electronic devices such as semiconductor devices and liquid crystal displays, the manufacture of micromachines in the field of MEMS (Micro Electro Mechanical Systems), the manufacture of photomasks and precision optical components, and the like. Etching that utilizes plasma is low-cost and high-speed and is advantageous also in that environmental pollution can be reduced because chemicals are not used.

In such etching that utilizes plasma, end point detection of the etching is performed to suppress under-etching and over-etching.

Technology for the end point detection of the etching is known in which the end point of the etching is detected by analyzing plasma light emission (for example, refer to Patent Literature 1).

In such technology, the end point of the etching is detected by detecting light of a designated wavelength of the plasma light emission using a detector and utilizing the fluctuation of the intensity of the light of the designated wavelength when the foundation is exposed.

However, there is a risk that the light emission intensity of the plasma may undesirably change in the case where the process conditions (e.g., the processing pressure, the applied power, and the like) fluctuate. Because the light emission intensity does not change until the foundation is exposed by the etching, there is also a risk that the foundation may be excessively etched or may be damaged.

Therefore, technology has been proposed to detect the end point of the etching by detecting the intensity of coherent light due to light reflected at the surface of the film to be etched and light reflected at the interface between the film to be etched and the foundation (referring to Patent Literature 2).

In the technology discussed in Patent Literature 2, the end point of the etching is detected by utilizing a periodic change of the intensity of the coherent light as the film thickness decreases due to the etching.

Therefore, because the point in time when the foundation is exposed can be known beforehand, excessive etching and damage of the foundation can be suppressed. Because the point in time when the foundation is exposed can be known beforehand, even in the case where the process conditions fluctuate and the intensity of the coherent light changes after this point in time is known, effects of the change of the intensity of the coherent light can be suppressed.

However, in the technology discussed in Patent Literature 2, the effects of the resist mask (the etching mask) provided on the surface of the film to be etched are not considered. Therefore, in the case where the proportion of the resist portion of the resist mask is high (in the case where the opening ratio is low), the intensity of the coherent light as viewed from the entire detection region decreases; and there is a risk that the detection precision may undesirably decrease. In particular, there is a risk that the detection precision may decrease further as the opening ratio decreases with the downscaling of recent years. In such a case, if only the etching portion (the opening portion of the resist mask) is detected, the effect of the resist portion of the resist mask can be reduced because the detection object is designated. However, if only the etching portion (the opening portion of the resist mask) is detected, there is a risk that a new problem occurs in that the positional alignment of the detection position is difficult because a minute portion is detected.

### CITATION LIST

### [Patent Literature]

[Patent Citation 1] JP-A 9-36090 (1997)
[Patent Citation 2] JP-A 10-64884 (1998)

### SUMMARY OF INVENTION

### Technical Problem

The invention provides a plasma etching apparatus and a plasma etching method that can increase the detection precision of an end point of etching.

### Solution to Problem

According to an aspect of an embodiment of the invention, there is provided a plasma etching apparatus including: a processing container capable of maintaining an atmosphere depressurized below atmospheric pressure; a depressurization unit configured to depressurize an interior of the processing container to a prescribed pressure; a placement unit provided in the interior of the processing container, the placement unit being configured to place a processing object; a discharge tube provided at a position isolated from the processing container, the discharge tube having a region in an interior of the discharge tube used to generate plasma; an introduction waveguide tube configured to cause microwaves radiated from a microwave production unit to propagate to introduce the microwaves to the region used to generate the plasma; a gas supply unit configured to supply a process gas to the region used to generate the plasma; a transport tube configured to link the discharge tube to the processing container; a detection window provided in a wall surface of the processing container, the detection window being configured to transmit light; a coherent light detection unit including a plurality of light receiving devices in a light reception surface configured to receive coherent light emitted from a surface of a processing object placed in the placement unit; and a control unit configured to detect an end point of etching based on an output from the coherent light detection unit, the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

According to another aspect of the invention, there is provided a plasma etching apparatus including: a processing container capable of maintaining an atmosphere depressurized below atmospheric pressure, the processing container having a region in an interior of the processing container used to generate plasma; a depressurization unit configured to depressurize the interior of the processing container to a prescribed pressure; a placement unit provided in the interior of the processing container, the placement unit being configured to place a processing object; a plasma generation unit configured to generate the plasma by supplying electromagnetic energy to the region used to generate the plasma; a gas supply unit configured to supply a process gas to the region used to generate the plasma; a detection window provided in a wall surface of the processing container, the detection window being configured to transmit light; a coherent light detection unit including a plurality of light receiving devices in a light reception surface configured to receive coherent light emitted from a surface of a processing object placed in the placement unit; and a control unit configured to detect an end point of etching based on an output from the coherent light detection unit, the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

According to another aspect of the invention, there is provided plasma etching apparatus including: a processing container capable of maintaining an atmosphere depressurized below atmospheric pressure; a depressurization unit configured to depressurize an interior of the processing container to a prescribed pressure; a placement unit provided in the interior of the processing container, the placement unit being configured to place a processing object; a discharge tube provided at a position isolated from the processing container, the discharge tube having a region in an interior of the discharge tube used to generate plasma; an introduction waveguide tube configured to cause microwaves radiated from a microwave production unit to propagate to introduce the microwaves to the region used to generate the plasma; a gas supply unit configured to supply a process gas to the region used to generate the plasma; a transport tube configured to link the discharge tube to the processing container; a detection window provided in a wall surface of the processing container, the detection window being configured to transmit light; a light source configured to irradiate light via the detection window onto a surface of a processing object placed in the placement unit; a coherent light detection unit including a plurality of light receiving devices in a light reception surface configured to receive coherent light emitted from the surface of the processing object placed in the placement unit; and a control unit configured to detect an end point of etching based on an output from the coherent light detection unit, the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

According to another aspect of the invention, there is provided plasma etching apparatus including: a processing container capable of maintaining an atmosphere depressurized below atmospheric pressure, the processing container having a region in an interior of the processing container used to generate plasma; a depressurization unit configured to depressurize the interior of the processing container to a prescribed pressure; a placement unit provided in the interior of the processing container, the placement unit being configured to place a processing object; a plasma generation unit configured to generate the plasma by supplying electromagnetic energy to the region used to generate the plasma; a gas supply unit configured to supply a process gas to the region used to generate the plasma; a detection window provided in a wall surface of the processing container, the detection window being configured to transmit light; a light source configured to irradiate light via the detection window onto a surface of a processing object placed in the placement unit; a coherent light detection unit including a plurality of light receiving devices in a light reception surface configured to receive coherent light emitted from the surface of the processing object placed in the placement unit; and a control unit configured to detect an end point of etching based on an output from the coherent light detection unit, the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

According to another aspect of the invention, a plasma etching method is configured to generate plasma in an atmosphere depressurized below atmospheric pressure, produce plasma products by exciting a process gas supplied toward the plasma, and use the plasma products to perform etching of a processing object, the plasma etching method including: detecting coherent light from the processing object by using a coherent light detection unit including a plurality of light receiving devices in a light reception surface; and detecting an end point of etching based on an intensity of the coherent light by using an output from the light receiving devices of a detection region of the coherent light detection unit to extract an output of the light receiving device of a portion of the detection region corresponding to an etching portion, the intensity of the coherent light being determined from the output of the light receiving device of the portion of the detection region corresponding to the etching portion.

### Advantageous Effects of Invention

According to the invention, a plasma etching apparatus and a plasma etching method that can increase the detection precision of an end point of etching are provided.

### BRIEF DESCRIPTION OF DRAWINGS

FIG. 1 is a schematic cross-sectional view illustrating a plasma etching apparatus according to a first embodiment of the invention.

FIGS. 2A and 2B are a schematic view illustrating the extraction of the etching portion (the opening portion of the resist mask).

FIG. 3 is a schematic cross-sectional view illustrating a plasma etching apparatus according to a second embodiment of the invention.

FIG. 4 is a schematic cross-sectional view illustrating a plasma etching apparatus according to a third embodiment of the invention.

### DESCRIPTION OF EMBODIMENTS

Embodiments of the invention will now be illustrated with reference to the drawings. Similar components in the drawings are marked with like reference numerals, and a detailed description is omitted as appropriate.

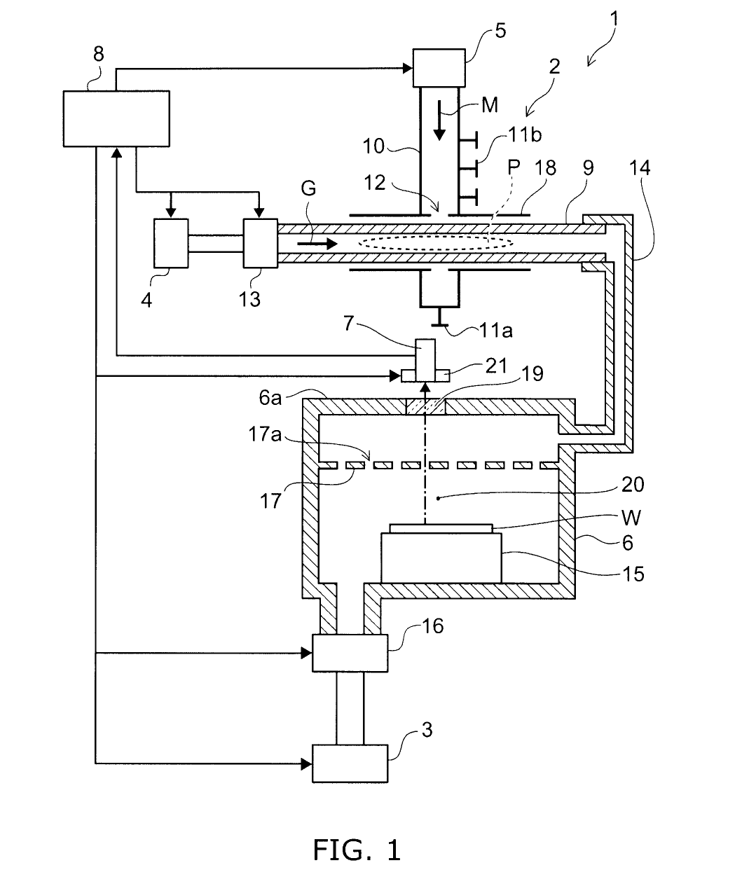

FIG. 1 is a schematic cross-sectional view illustrating a plasma etching apparatus according to a first embodiment of the invention.

The plasma etching apparatus 1 illustrated in FIG. 1 is a microwave excitation-type plasma etching apparatus that is generally called a “CDE (Chemical Dry Etching) apparatus.” In other words, this is an example of a plasma etching apparatus that performs processing of a processing object by producing plasma products from a process gas by using plasma that is excited and generated using microwaves.

As illustrated in FIG. 1, the plasma etching apparatus 1 includes a plasma generation unit 2, a depressurization unit 3, a gas supply unit 4, a microwave production unit 5, a processing container 6, a coherent light detection unit 7, a control unit 8, and the like.

The plasma generation unit 2 generates plasma P by supplying microwaves (electromagnetic energy) to a region where the plasma P is generated.

A discharge tube 9 and an introduction waveguide tube 10 are provided in the plasma generation unit 2.

The discharge tube 9 is provided at a position isolated from the processing container 6 and has a region in the interior of the discharge tube 9 used to generate plasma. The discharge tube 9 has a pipe configuration and is made of a material that has a high transmittance with respect to microwaves M and is not easily etched. For example, the discharge tube 9 can be made of a dielectric such as alumina, quartz, and the like.

A shielding portion 18 having a pipe configuration is provided to cover an outer circumferential surface of the discharge tube 9. A prescribed gap is provided between the inner circumferential surface of the shielding portion 18 and the outer circumferential surface of the discharge tube 9; and the shielding portion 18 and the discharge tube 9 are disposed to be substantially coaxial. This gap has dimensions such that the microwaves M do not leak. Therefore, the leakage of the microwaves M can be suppressed by the shielding portion 18.

The introduction waveguide tube 10 is connected to the shielding portion 18 to be substantially orthogonal to the discharge tube 9. A terminal matching unit 11a is provided at a terminal of the introduction waveguide tube 10. A stub tuner 11b is provided at the inlet side of the introduction waveguide tube 10 (the introduction side of the microwaves M). The introduction waveguide tube 10 introduces the microwaves M to the region where the plasma P is generated by causing the microwaves M radiated from the microwave production unit 5 described below to propagate.

A slot 12 having an annular configuration is provided in a connection portion between the introduction waveguide tube 10 and the shielding portion 18. The slot 12 is a slot for radiating the microwaves M that are waveguided through the interior of the introduction waveguide tube 10 toward the discharge tube 9. As described below, although the plasma P is generated in the interior of the discharge tube 9, the portion opposing the slot 12 is substantially the center of the region where the plasma P is generated.

The microwave production unit 5 is provided at one end of the introduction waveguide tube 10. The microwave production unit 5 is configured to produce the microwaves M of a prescribed frequency (e.g., 2.75 GHz) and radiate the microwaves M toward the introduction waveguide tube 10.

The gas supply unit 4 is connected to one end of the discharge tube 9 with an interposed flow rate control unit (Mass Flow Controller (MFC)) 13. Then, a process gas G can be supplied from the gas supply unit 4 via the flow rate control unit 13 to the region inside the discharge tube 9 used to generate the plasma. The supply amount of the process gas G can be adjusted by the control of the flow rate control unit 13 by the control unit 8.

One end of a transport tube 14 is connected to the other end of the discharge tube 9; and the other end of the transport tube 14 is connected to the processing container 6. In other words, the transport tube 14 links the discharge tube 9 to the processing container 6. The transport tube 14 is made of a material capable of withstanding the corrosion due to neutral active species, e.g., quartz, stainless steel, ceramics, fluorocarbon resin, and the like.

The processing container 6 has a substantially cylindrical configuration with a bottom; and the upper end of the processing container 6 is closed with a top plate 6a. A placement unit 15 having a not-illustrated built-in electrostatic chuck is provided in the interior of the processing container 6; and a processing object W (e.g., a semiconductor wafer, a glass substrate, and the like) can be placed and held at the upper surface (the placement surface) of the placement unit 15.

The depressurization unit 3 such as a turbo molecular pump (TMP) and the like is connected to the bottom surface of the processing container 6 with an interposed pressure control unit (Auto Pressure Controller (APC)) 16. The depressurization unit 3 depressurizes the interior of the processing container 6 to a prescribed pressure. The pressure control unit 16 controls the internal pressure of the processing container 6 to be the prescribed pressure based on the output of a not-illustrated vacuum gauge that detects the internal pressure of the processing container 6. In other words, the processing container 6 is configured to contain the processing object W such as a semiconductor wafer, a glass substrate, and the like and maintain an atmosphere depressurized below atmospheric pressure.

A flow straightening plate 17 is provided lower than the connection portion from the transport tube 14 and above the placement unit 15 to oppose the upper surface (the placement surface) of the placement unit 15. The flow straightening plate 17 is a flow straightening plate for straightening the flow of the gas including the neutral active species that is introduced from the transport tube 14 such that the amount of the neutral active species is substantially uniform on the processing surface of the processing object W. The flow straightening plate 17 is a substantially circular plate-like body in which many holes 17a are provided and is fixed to the inner wall of the processing container 6. The region between the flow straightening plate 17 and the upper surface (the placement surface) of the placement unit 15 is used as a processing space 20 where the processing of the processing object is performed. The interior wall surface of the processing container 6 and the surface of the flow straightening plate 17 are covered with a material (e.g., polytetrafluoroethylene (PTFE), a ceramic material such as alumina, and the like) that does not react easily with the neutral active species.

A detection window 19 is provided in the wall surface of the processing container 6. The detection window 19 is made of a transparent material; and light can pass through the detection window 19. The detection window 19 is provided at a position that can look onto the surface of the processing object W placed on the upper surface (the placement surface) of the placement unit 15. For example, as illustrated in FIG. 1, the detection window 19 can be provided in the top plate 6a opposing the upper surface (the placement surface) of the placement unit 15. However, the position at which the detection window 19 is provided is not limited to the top plate 6a; and the detection window 19 can be appropriately provided at a position that can look onto the surface of the processing object W placed on the upper surface (the placement surface) of the placement unit 15, e.g., the side wall, the top plate 6a, and the like of the processing container 6.

The coherent light detection unit 7 is provided at a position that can look via the detection window 19 onto the surface of the processing object W placed on the upper surface (the placement surface) of the placement unit 15.

The coherent light detection unit 7 detects the intensity of the coherent light due to the light reflected at the surface of the film to be etched and the light reflected at the interface between the film to be etched and the foundation.

Here, the intensity of the coherent light changes periodically as the film thickness decreases due to the etching and becomes substantially constant when the foundation is exposed. The film thickness can be calculated if the period when the intensity of the coherent light changes can be detected because the period when the intensity of the coherent light changes has a correlation with the wavelength of the light and the refractive index and the film thickness of the film to be etched. Therefore, the point in time when the etching ends, i.e., the end point of the etching, can be detected.

Multiple light receiving devices are provided in a light reception surface of the coherent light detection unit 7. The light receiving devices output electrical signals corresponding to the intensity of the coherent light that is received. In other words, the coherent light detection unit 7 includes multiple light receiving devices in a light reception surface configured to receive the coherent light emitted from the surface of the processing object placed in the placement unit 15. The disposition form of the light receiving devices is not particularly limited; and the light receiving devices may be, for example, juxtaposed in one column or packed in a planar configuration such as a lattice configuration and the like. However, in the case where the light receiving devices are packed in a planar configuration, the positional alignment of the detection position is easy because the detection region can have a planar configuration.

For example, a CCD (Charge Coupled Device) sensor and the like are examples of the coherent light detection unit 7.

Here, a resist mask (an etching mask) is provided on the surface of the film to be etched. Therefore, in the case where the proportion of the resist portion of the resist mask is high (in the case where the opening ratio is low), there is a risk that the intensity of the coherent light when the detection region is viewed as an entirety may decrease and the detection precision may undesirably decrease. In particular, there is a risk that the detection precision may decrease further as the opening ratio decreases with the downscaling of recent years. In such a case, if only the etching portion (the opening portion of the resist mask) is detected, the effect of the resist portion of the resist mask can be reduced because the detection object is designated. However, there is a risk that a new problem occurs in that the positional alignment of the detection position is difficult because a minute portion is detected if only the etching portion (the opening portion of the resist mask) is detected.

Therefore, in this embodiment, the multiple light receiving devices are provided in the light reception surface of the coherent light detection unit 7 such that the etching portion (the opening portion of the resist mask) can be extracted from the detection region. Then, the end point of the etching is detected based on the intensity of the coherent light of the etching portion (the opening portion of the resist mask) that is extracted. Details relating to the extraction of the etching portion (the opening portion of the resist mask) and the detection of the end point of the etching are described below.

A light source 21 is provided at a position from which light can be irradiated via the detection window 19 onto the surface of the processing object W placed on the upper surface (the placement surface) of the placement unit 15.

The coherent light can be produced by utilizing the light from the plasma P leaking out via the transport tube 14 into the processing container 6 and the light emission occurring inside the processing container 6. Therefore, it is not always necessary to provide the light source 21. However, considering that the intensity of the light from the plasma P fluctuates and the intensities of the light leaking out into the processing container 6 and the light emission occurring inside the processing container 6 are low, it is favorable for the light source 21 to be provided. The light source 21 is not particularly limited; and, for example, a light source including a metal halide lamp, a halogen lamp, and the like, a light source that is capable of emitting laser light, and the like are examples of the light source 21.

In the case where laser light is used, it is favorable for laser light that is scanned to be irradiated onto the surface of the processing object W.

The control unit 8 controls the depressurization unit 3, the gas supply unit 4, the microwave production unit 5, the pressure control unit 16, the flow rate control unit 13, the light source 21, and the like.

The control unit 8 extracts the etching portion (the opening portion of the resist mask) from the detection region based on the electrical signals from the light receiving devices provided in the coherent light detection unit 7. Then, the end point of the etching is detected based on the intensity of the coherent light of the etching portion (the opening portion of the resist mask) that is extracted. In such a case, the control unit 8 extracts the etching portion (the opening portion of the resist mask) from a detection region having a prescribed size and detects the end point of the etching based on the intensity of the coherent light of the etching portion (the opening portion of the resist mask). Described in more detail, the control unit 8 uses the output from the light receiving devices of a detection region 7a of the coherent light detection unit 7 to extract the output of the light receiving device of the portion of the detection region 7a corresponding to the etching portion (the opening portion of the resist mask) to detect the end point of the etching based on the intensity of the coherent light determined from the output of the light receiving device of the portion of the detection region 7a corresponding to the etching portion (the opening portion of the resist mask).

Thus, the extraction of the etching portion (the opening portion of the resist mask) from the detection region 7a is performed based on the output of the light receiving devices of the detection region 7a and the output of the light receiving device of the portion of the detection region 7a corresponding to the etching portion (the opening portion of the resist mask). However, in the specification, expressions such as simply “extraction of the etching portion (the opening portion of the resist mask)” and the like are used to avoid complexity.

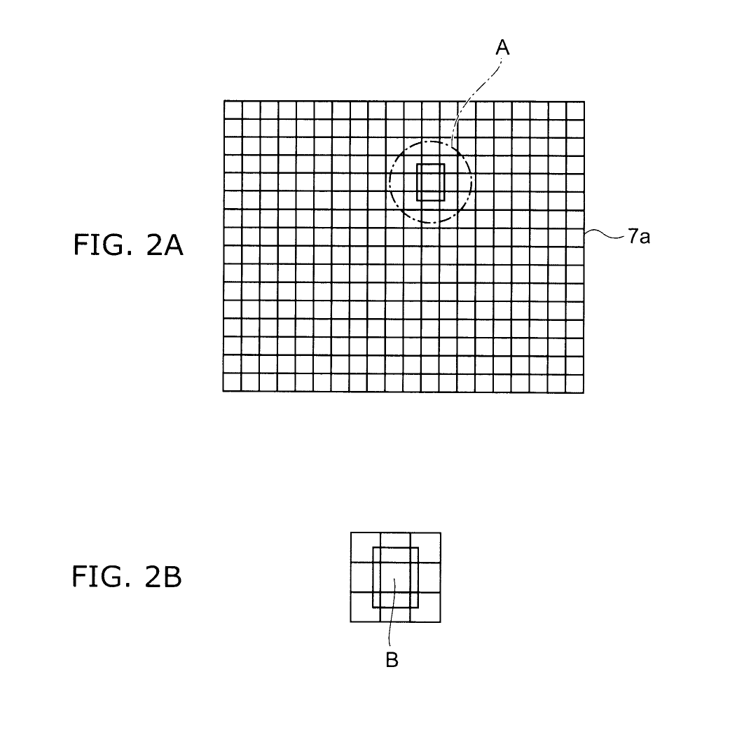

FIGS. 2A and 2B are a schematic view illustrating the extraction of the etching portion (the opening portion of the resist mask). FIG. 2A is a schematic view illustrating the appearance of the detection of the detection region 7a of the coherent light detection unit 7; and FIG. 2B is an enlarged view of portion A of FIG. 2A.

In such a case, multiple pixels (the light receiving devices) are packed in a lattice configuration in the light reception surface of the coherent light detection unit 7; and an electrical signal corresponding to the intensity of the coherent light is output for each of the pixels (the light receiving devices) of the detection region 7a.

The electrical signals from the coherent light detection unit 7 are sent to the control unit 8; and the intensity of the coherent light is detected for each of the pixels (the light receiving devices).

Here, the intensity change amount of the coherent light is monitored for each of the pixels (the light receiving devices); and the portion in which the intensity change occurs can be extracted as the etching portion (the opening portion of the resist mask). For example, the cross hatching portion of FIG. 2A can be extracted as the etching portion (the opening portion of the resist mask).

Then, the portion of the etching portion (the opening portion of the resist mask) that is extracted for which the fluctuation amount of the intensity of the coherent light is the largest is used as the detection object.

For example, a pixel B of FIG. 2B is used as the detection object because the fluctuation amount of the intensity of the coherent light is greater than that of pixels around the pixel B.

Automatic discrimination methods of the pixel having the largest fluctuation amount of the intensity of the coherent light includes a method in which the time derivative of the intensity of the coherent light is monitored and the pixel having the largest time derivative is taken to be the pixel having the largest fluctuation amount of the intensity of the coherent light.

Further, instead of extracting one pixel as the detection object, a region having a large fluctuation amount of the intensity of the coherent light (e.g., the region of FIG. 2B made of the pixel B and pixels around the pixel B) also can be used as the detection object. In such a case, for example, several pixels for which the fluctuation amount of the intensity of the coherent light is largest can be monitored together; and the average of these pixels can be determined.

As illustrated above, the effect of the resist portion of the resist mask can be reduced if the etching portion (the opening portion of the resist mask) is extracted from the detection region 7a having the prescribed size because the detection object is designated. Further, the designation of the detection object (the positional alignment of the detection) can be easy even in the case where the etching portion (the opening portion of the resist mask) is minute. Therefore, the detection precision of the end point of the etching can be increased.

Also, effects such as noise and the like can be reduced further if a region having a large fluctuation amount of the intensity of the coherent light is used as the detection object and the end point of the etching is detected based on the average of the intensity of the coherent light of this region.

Operations of the plasma etching apparatus 1 and a plasma etching method according to this embodiment will now be illustrated.

First, the processing object W (e.g., a semiconductor wafer, a glass substrate, and the like) is transferred into the processing container 6 by a not-illustrated transfer apparatus and is placed and held on the placement unit 15.

Then, the interior of the processing container 6 is depressurized to a prescribed pressure by the depressurization unit 3. At this time, the pressure inside the processing container 6 is adjusted by the pressure control unit 16. The interior of the discharge tube 9 that communicates with the processing container 6 also is depressurized.

Continuing, plasma products including neutral active species are produced by the plasma generation unit 2. Namely, first, a prescribed flow rate of the process gas G (e.g., CF₄ and the like) is supplied from the gas supply unit 4 via the flow rate control unit 13 into the discharge tube 9. On the other hand, the microwaves M of a prescribed power are radiated from the microwave production unit 5 into the introduction waveguide tube 10. The radiated microwaves M are waveguided through the introduction waveguide tube 10 and are radiated via the slot 12 toward the discharge tube 9.

The microwaves M that are radiated toward the discharge tube 9 are radiated into the discharge tube 9 by propagating through the surface of the discharge tube 9. Thus, the plasma P is generated by the energy of the microwaves M that are radiated into the discharge tube 9. Then, when the electron density inside the plasma P that is generated reaches or exceeds the density (the cutoff density) at which the microwaves M that are supplied via the discharge tube 9 can be shielded, the microwaves M are reflected such that the microwaves M enter the space inside the discharge tube 9 only to a constant distance (the skin depth) from the interior wall surface of the discharge tube 9. Therefore, a standing wave of the microwaves M is formed between the reflective surface of the microwaves M and the lower surface of the slot 12. As a result, the reflective surface of the microwaves M becomes a plasma excitation surface; and the plasma P is stably excited and generated at this plasma excitation surface. Plasma products such as neutral active species, ions, and the like are produced by the process gas G being excited and activated inside the plasma P that is excited and generated at this plasma excitation surface.

The gas including the plasma products that are produced is transferred into the processing container 6 via the transport tube 14. At this time, the ions and the like that have short lives cannot reach the processing container 6; and only the neutral active species that have long lives reach the processing container 6. The gas including the neutral active species that are introduced into the processing container 6 is straightened by the flow straightening plate 17 to reach the surface of the processing object W; and the etching is performed. In this embodiment, mainly isotropic processing (isotropic etching) by the neutral active species is performed.

Then, the end point of the etching is detected.

First, as described above, the intensity of the coherent light due to the light reflected at the surface of the film to be etched and the light reflected at the interface between the film to be etched and the foundation is detected by the coherent light detection unit 7. In such a case, the electrical signal from the coherent light detection unit 7 is sent to the control unit 8; and the intensity of the coherent light is detected for each of the pixels (the light receiving devices). Then, the etching portion (the opening portion of the resist mask) is extracted from the difference of the intensities of the coherent light.

Then, the point in time when the etching ends, i.e., the end point of the etching, is detected by using the portion for which the fluctuation amount of the intensity of the coherent light is the largest as the detection object, detecting the period of the intensity change of the coherent light of this portion, and calculating the film thickness from the correlation between the period, the wavelength of the light, and the refractive index and the film thickness of the film to be etched.

When detecting the end point of the etching, light can be irradiated from the light source 21 toward the detection object portion. In such a case, the coherent light also can be produced by utilizing the light from the plasma P leaking out via the transport tube 14 into the processing container 6 and the light emission occurring inside the processing container 6. However, considering that the intensity of the light from the plasma P fluctuates and the intensities of the light leaking out into the processing container 6 and the light emission occurring inside the processing container 6 are low, it is favorable for the light to be irradiated from the light source 21 toward the detection object portion.

In the case where it is determined by the control unit 8 that the etching has ended, the production of the plasma products by the plasma generation unit 2 is stopped.

The processing object W for which the etching has ended is transferred out of the processing container 6 by a not-illustrated transfer apparatus. Subsequently, if necessary, the etching described above is repeated.

As illustrated above, the plasma etching method according to this embodiment is a plasma etching method that generates the plasma P in an atmosphere depressurized below atmospheric pressure, produces the plasma products by exciting the process gas G supplied toward the plasma P, and uses the plasma products that are produced to perform etching of the processing object W, where the plasma etching method includes: a process of detecting the coherent light from the processing object W by using the coherent light detection unit 7 including the multiple light receiving devices in a light reception surface; and a process of detecting the end point of the etching based on the intensity of the coherent light of an etching portion (an opening portion of the resist mask) by extracting the etching portion (the opening portion of the resist mask) from the detection region 7a having a prescribed size.

The process of detecting the end point of the etching also can include using a region having a large fluctuation amount of the intensity of the coherent light as the detection object and detecting the end point of the etching based on the average of the intensity of the coherent light of this region.

According to this embodiment, the detection object (the etching portion) can be designated because the coherent light detection unit 7 that includes the multiple light receiving devices is provided and because the etching portion (the opening portion of the resist mask) is extracted from the detection region 7a having the prescribed size. Therefore, the effect of the resist portion (the non-etching portion) of the resist mask can be suppressed. Also, effects such as noise and the like can be reduced. The designation of the detection object (the positional alignment of the detection) can be easy even in the case where the etching portion (the opening portion of the resist mask) is minute. Therefore, the detection precision of the end point of the etching can be increased.

Effects such as noise and the like can be reduced further if a region having a large fluctuation amount of the intensity of the coherent light is used as the detection object and the end point of the etching is detected based on the average of the intensity of the coherent light of this region.

Further, higher productivity, yield, quality, and the like can be realized.

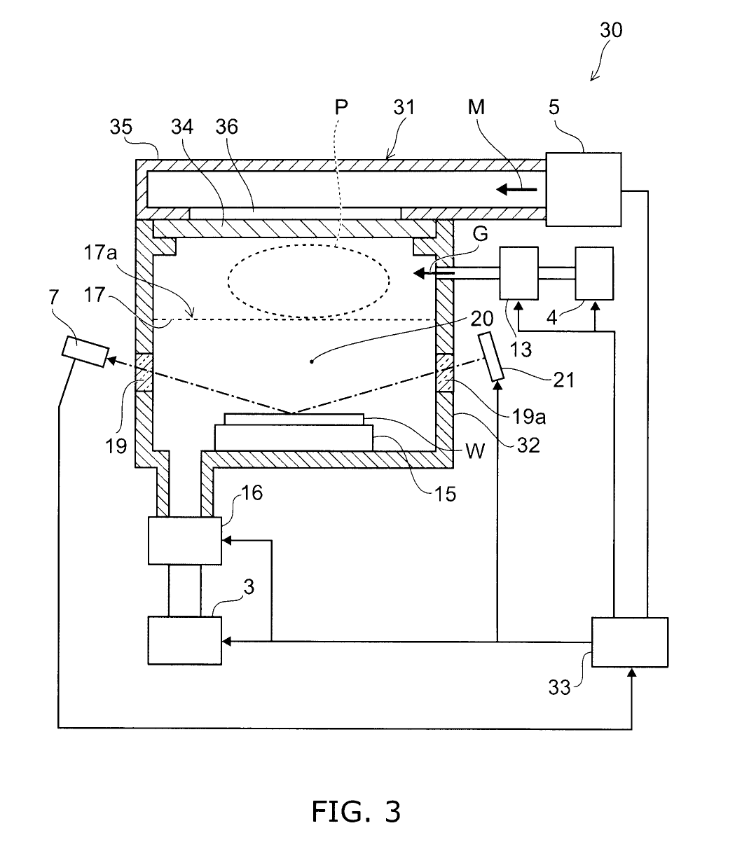

FIG. 3 is a schematic cross-sectional view illustrating a plasma etching apparatus according to a second embodiment of the invention.

The plasma etching apparatus 30 illustrated in FIG. 3 is a microwave excitation-type plasma etching apparatus that is generally called a “SWP (Surface Wave Plasma)” apparatus. In other words, this is an example of a plasma etching apparatus that performs processing of a processing object by producing plasma products from a process gas by using plasma that is excited and generated using microwaves.

As illustrated in FIG. 3, the plasma etching apparatus 30 includes a plasma generation unit 31, the depressurization unit 3, the gas supply unit 4, the microwave production unit 5, a processing container 32, the coherent light detection unit 7, a control unit 33, and the like.

The plasma generation unit 31 generates the plasma P by supplying microwaves (electromagnetic energy) to a region where the plasma P is generated.

A transmissive window 34 and an introduction waveguide tube 35 are provided in the plasma generation unit 31. The transmissive window 34 has a flat plate configuration and is made of a material that has a high transmittance with respect to the microwaves M and is not easily etched. For example, the transmissive window 34 can be made of a dielectric such as alumina, quartz, and the like. The transmissive window 34 is provided at the upper end of the processing container 32 to be airtight.

The introduction waveguide tube 35 is provided outside the processing container 32 at the upper surface of the transmissive window 34. Although not illustrated, a terminal matching unit and a stub tuner also can be appropriately provided. The introduction waveguide tube 35 introduces the microwaves M to the region where the plasma P is generated by causing the microwaves M radiated from the microwave production unit 5 to propagate.

A slot 36 is provided in the connection portion between the introduction waveguide tube 35 and the transmissive window 34. The slot 36 is a slot for radiating the microwaves M that are waveguided through the interior of the introduction waveguide tube 35 toward the transmissive window 34.

The microwave production unit 5 is provided at one end of the introduction waveguide tube 35. The microwave production unit 5 is configured to produce the microwaves M of a prescribed frequency (e.g., 2.75 GHz) and radiate the microwaves M toward the introduction waveguide tube 35.

The gas supply unit 4 is connected to the side wall upper portion of the processing container 32 with the flow rate control unit (Mass Flow Controller (MFC)) 13 interposed. Then, the process gas G can be supplied from the gas supply unit 4 via the flow rate control unit 13 to the region inside the processing container 32 where the plasma P is generated. The supply amount of the process gas G can be adjusted by the control of the flow rate control unit 13 by the control unit 33.

The processing container 32 has a substantially cylindrical configuration with a bottom; and the placement unit having a not-illustrated built-in electrostatic chuck is provided in the interior of the processing container 32. The processing object W (e.g., a semiconductor wafer, a glass substrate, and the like) can be placed and held at the upper surface (the placement surface) of the placement unit 15.

The depressurization unit 3 such as a turbo molecular pump (TMP) and the like is connected to the bottom surface of the processing container 32 with the pressure control unit (Auto Pressure Controller (APC)) 16 interposed. The depressurization unit 3 depressurizes the interior of the processing container 32 to a prescribed pressure. The pressure control unit 16 controls the internal pressure of the processing container 32 to be the prescribed pressure based on the output of a not-illustrated vacuum gauge that detects the internal pressure of the processing container 32. In other words, the processing container 32 has a region in the interior of the processing container 32 where the plasma P is generated and is configured to maintain an atmosphere depressurized below atmospheric pressure.

The flow straightening plate 17 is provided lower than the connection portion from the gas supply unit 4 and above the placement unit 15 to oppose the upper surface (the placement surface) of the placement unit 15. The flow straightening plate 17 is a flow straightening plate for straightening the flow of the gas including the plasma products that are produced in the region where the plasma P is generated such that the amount of the plasma products is substantially uniform on the processing surface of the processing object W.

The flow straightening plate 17 is a substantially circular plate-like body in which many holes 17a are provided and is fixed to the inner wall of the processing container 32. The region between the flow straightening plate 17 and the upper surface (the placement surface) of the placement unit 15 is used as the processing space 20 where the processing of the processing object is performed. The interior wall surface of the processing container 32 and the surface of the flow straightening plate 17 are covered with a material (e.g., polytetrafluoroethylene (PTFE), a ceramic material such as alumina, and the like) that does not react easily with the neutral active species.

The detection windows 19 and 19a are provided in the wall surface of the processing container 32. The detection windows 19 and 19a are made of transparent materials; and light can pass through the detection windows 19 and 19a. The detection windows 19 and 19a are provided at positions that can look onto the surface of the processing object W placed on the upper surface (the placement surface) of the placement unit 15. For example, as illustrated in FIG. 3, the detection windows 19 and 19a can be provided in the side wall of the processing container 32. However, the positions at which the detection windows 19 and 19a are provided are not limited to the side wall of the processing container 32; and the detection windows 19 and 19a can be appropriately provided at positions that can look onto the surface of the processing object W placed on the upper surface (the placement surface) of the placement unit 15, e.g., the ceiling and the like of the processing container 32.

The coherent light detection unit 7 described above is provided at a position that can look via the detection window 19 onto the surface of the processing object W placed on the upper surface (the placement surface) of the placement unit 15.

The detection window 19a and the light source 21 are provided at positions at which the light that is emitted from the light source 21 and reflected at the surface of the processing object W can be incident on the coherent light detection unit 7.

In this embodiment as well, the multiple light receiving devices are provided in the light reception surface of the coherent light detection unit 7; and the etching portion (the opening portion of the resist mask) can be extracted from the detection region. Then, the end point of the etching is detected based on the intensity of the coherent light of the etching portion (the opening portion of the resist mask) that is extracted.

The coherent light can be produced by utilizing the light from the plasma P that is generated in the region where the plasma P is generated. Therefore, it is not always necessary to provide the light source 21. However, considering that the intensity of the light from the plasma P fluctuates, it is favorable for the light source 21 to be provided. The light source 21 is not particularly limited; and, for example, a light source including a metal halide lamp, a halogen lamp, and the like, a light source that is capable of emitting laser light, and the like are examples of the light source 21.

In the case where laser light is used, it is favorable for laser light that is scanned to be irradiated onto the surface of the processing object W.

The control unit 33 controls the depressurization unit 3, the gas supply unit 4, the microwave production unit 5, the pressure control unit 16, the flow rate control unit 13, the light source 21, and the like.

The control unit 33 extracts the etching portion (the opening portion of the resist mask) from the detection region based on the electrical signals from the light receiving devices provided in the coherent light detection unit 7. Then, the end point of the etching is detected based on the intensity of the coherent light of the etching portion (the opening portion of the resist mask) that is extracted. In other words, the control unit 33 extracts the etching portion (the opening portion of the resist mask) from a detection region having a prescribed size and detects the end point of the etching based on the intensity of the coherent light of the etching portion (the opening portion of the resist mask). Details relating to the extraction of the etching portion (the opening portion of the resist mask) and the detection of the end point of the etching are similar to those described above and are therefore omitted.

Operations of the plasma etching apparatus 30 and a plasma etching method according to this embodiment will now be illustrated.

First, the processing object W (e.g., a semiconductor wafer, a glass substrate, and the like) is transferred into the processing container 32 by a not-illustrated transfer apparatus and is placed and held on the placement unit 15.

Then, the interior of the processing container 32 is depressurized to a prescribed pressure by the depressurization unit 3. At this time, the pressure inside the processing container 32 is adjusted by the pressure control unit 16.

Continuing, plasma products including neutral active species are produced by the plasma generation unit 31. Namely, first, a prescribed amount of the process gas G (e.g., CF₄ and the like) is supplied from the gas supply unit 4 via the flow rate control unit 13 to the region inside the processing container 32 where the plasma P is generated. On the other hand, the microwaves M of a prescribed power are radiated from the microwave production unit 5 into the introduction waveguide tube 35. The radiated microwaves M are waveguided through the introduction waveguide tube 35 and are radiated toward the transmissive window 34 via the slot 36.

The microwaves M that are radiated toward the transmissive window 34 are radiated into the processing container 32 by propagating through the surface of the transmissive window 34. Thus, the plasma P is generated by the energy of the microwaves M that are radiated into the processing container 32. Then, when the electron density inside the plasma P that is generated reaches or exceeds the density (the cutoff density) at which the microwaves M that are supplied via the transmissive window 34 can be shielded, the microwaves M are reflected such that the microwaves M enter the space inside the processing container 32 only to a constant distance (the skin depth) from the lower surface of the transmissive window 34. Therefore, a standing wave of the microwaves M is formed between the reflective surface of the microwaves M and the lower surface of the slot 36. As a result, the reflective surface of the microwaves M becomes a plasma excitation surface; and the plasma P is stably excited and generated at this plasma excitation surface. Plasma products such as neutral active species, ions, and the like are produced by the process gas G being excited and activated inside the plasma P that is excited and generated at this plasma excitation surface.

The gas including the plasma products that are produced is straightened by the flow straightening plate 17 to reach the surface of the processing object W; and the etching is performed. In this embodiment, ions and electrons are removed when the gas including the plasma products passes through the flow straightening plate 17. Therefore, mainly isotropic processing (isotropic etching) by the neutral active species is performed. The anisotropic processing (the anisotropic etching) also can be performed by ions being able to pass through the flow straightening plate 17 by adding a bias voltage.

Then, the end point of the etching is detected.

First, as described above, the intensity of the coherent light due to the light reflected at the surface of the film to be etched and the light reflected at the interface between the film to be etched and the foundation is detected by the coherent light detection unit 7. In such a case, the electrical signal from the coherent light detection unit 7 is sent to the control unit 33; and the intensity of the coherent light is detected for each of the pixels (the light receiving devices). Then, the portion in which the intensity change of the coherent light occurs is extracted as the etching portion (the opening portion of the resist mask).

Then, the point in time when the etching ends, i.e., the end point of the etching, is detected by using the portion for which the fluctuation amount of the intensity of the coherent light is the largest as the detection object, detecting the period of the intensity change of the coherent light of this portion, and calculating the film thickness from the correlation between the period, the wavelength of the light, and the refractive index and the film thickness of the film to be etched.

When detecting the end point of the etching, light can be irradiated from the light source 21 toward the detection object portion. In such a case, the coherent light also can be produced by utilizing the light from the plasma P that is generated in the region where the plasma P is generated. However, considering that the intensity of the light from the plasma P fluctuates, it is favorable for the light to be irradiated from the light source 21 toward the detection object portion.

In the case where it is determined by the control unit 33 that the etching has ended, the production of the plasma products by the plasma generation unit 31 is stopped.

The processing object W for which the etching has ended is transferred out of the processing container 32 by a not-illustrated transfer apparatus. Subsequently, if necessary, the etching described above is repeated.

As illustrated above, the plasma etching method according to this embodiment is a plasma etching method that generates the plasma P in an atmosphere depressurized below atmospheric pressure, produces the plasma products by exciting the process gas G supplied toward the plasma P, and uses the plasma products that are produced to perform etching of the processing object W, where the plasma etching method includes: a process of detecting the coherent light from the processing object W by using the coherent light detection unit 7 including the multiple light receiving devices in a light reception surface; and a process of detecting the end point of the etching based on the intensity of the coherent light of an etching portion (an opening portion of the resist mask) by extracting the etching portion (the opening portion of the resist mask) from the detection region 7a having a prescribed size.

Similarly to that described above, the process of detecting the end point of the etching also can include using a region having a large fluctuation amount of the intensity of the coherent light as the detection object and detecting the end point of the etching based on the average of the intensity of the coherent light of this region.

According to this embodiment, the detection object (the etching portion) can be designated because the coherent light detection unit 7 that includes the multiple light receiving devices is provided and because the etching portion (the opening portion of the resist mask) is extracted from the detection region 7a having the prescribed size. Therefore, the effect of the resist portion (the non-etching portion) of the resist mask can be suppressed. Also, effects such as noise and the like can be reduced. The designation of the detection object (the positional alignment of the detection) can be easy even in the case where the etching portion (the opening portion of the resist mask) is minute. Therefore, the detection precision of the end point of the etching can be increased.

Effects such as noise and the like can be reduced further if a region having a large fluctuation amount of the intensity of the coherent light is used as the detection object and the end point of the etching is detected based on the average of the intensity of the coherent light of this region.

Further, higher productivity, yield, quality, and the like can be realized.

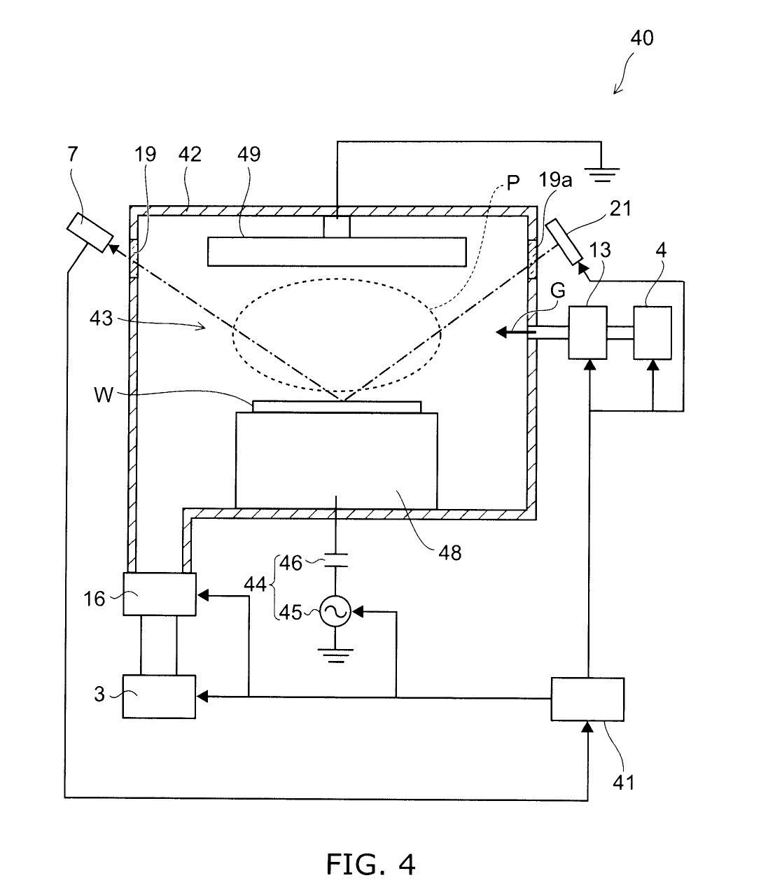

FIG. 4 is a schematic cross-sectional view illustrating a plasma etching apparatus according to a third embodiment of the invention.

The plasma etching apparatus 40 illustrated in FIG. 4 is a capacitively coupled plasma (CCP) processing apparatus that is generally called a “parallel plate-type RIE (Reactive Ion Etching) apparatus.” In other words, this is an example of a plasma etching apparatus that performs processing of a processing object by producing plasma products from the process gas G by using plasma generated by applying high frequency power to parallel-plate electrodes.

As illustrated in FIG. 4, the plasma etching apparatus 40 includes a plasma generation unit 43, the depressurization unit 3, the gas supply unit 4, a power source unit 44, a processing container 42, the coherent light detection unit 7, a control unit 41, and the like.

The processing container 42 has a substantially cylindrical configuration that is closed at both ends and has an airtight structure capable of maintaining a reduced-pressure atmosphere.

The plasma generation unit 43 that is configured to generate the plasma P is provided in the interior of the processing container 42.

The plasma generation unit 43 generates the plasma P by supplying electromagnetic energy to the region where the plasma P is generated.

A lower electrode 48 and an upper electrode 49 are provided in the plasma generation unit 43.

The lower electrode 48 is provided inside the processing container 42 below the region where the plasma P is generated. A not-illustrated holding unit for holding the processing object W is provided in the lower electrode 48. The not-illustrated holding unit can be, for example, an electrostatic chuck and the like. Therefore, the lower electrode 48 also is used as the placement unit that places and holds the processing object W in the upper surface (the placement surface).

The upper electrode 49 is provided to oppose the lower electrode 48. A power source 45 is connected to the lower electrode 48 with an interposed blocking capacitor 46; and the upper electrode 49 is grounded. Therefore, the plasma generation unit 43 can generate the plasma P by supplying electromagnetic energy to the region where the plasma P is generated.

The power source 45 and the blocking capacitor 46 are provided in the power source unit 44.

The power source 45 applies high frequency power of about 100 KHz to 100 MHz to the lower electrode 48. The blocking capacitor 46 is provided to obstruct the movement of electrons that are generated inside the plasma P and reach the lower electrode 48.

The depressurization unit 3 such as a turbo molecular pump (TMP) and the like is connected to the bottom surface of the processing container 42 with the pressure control unit (Auto Pressure Controller (APC)) 16 interposed. The depressurization unit 3 depressurizes the interior of the processing container 42 to a prescribed pressure. The pressure control unit 16 controls the internal pressure of the processing container 42 to be the prescribed pressure based on the output of a not-illustrated vacuum gauge that detects the internal pressure of the processing container 42. In other words, the processing container 42 has a region in the interior of the processing container 42 where the plasma P is generated and is configured to maintain an atmosphere depressurized below atmospheric pressure.

The gas supply unit 4 is connected to the side wall upper portion of the processing container 42 with the flow rate control unit (Mass Flow Controller (MFC)) 13 interposed. Then, the process gas G can be supplied from the gas supply unit 4 via the flow rate control unit 13 to the region inside the processing container 42 where the plasma P is generated. The supply amount of the process gas G can be adjusted by the control of the flow rate control unit 13 by the control unit 41.

The detection windows 19 and 19a are provided in the wall surface of the processing container 42. The detection windows 19 and 19a are made of transparent materials; and light can pass through the detection windows 19 and 19a. The detection windows 19 and 19a are provided at positions that can look onto the surface of the processing object W placed on the upper surface (the placement surface) of the lower electrode 48. For example, as illustrated in FIG. 4, the detection windows 19 and 19a can be provided in the side wall of the processing container 42. However, the positions at which the detection windows 19 and 19a are provided are not limited to the side wall of the processing container 42; and the detection windows 19 and 19a can be appropriately provided at positions that can look onto the surface of the processing object W placed on the upper surface (the placement surface) of the lower electrode 48, e.g., the ceiling and the like of the processing container 42.

The coherent light detection unit 7 is provided at a position that can look via the detection window 19 onto the surface of the processing object W placed on the upper surface (the placement surface) of the lower electrode 48.

The detection window 19a and the light source 21 are provided at positions at which the light that is emitted from the light source 21 and reflected at the surface of the processing object W can be incident on the coherent light detection unit 7.

In this embodiment as well, the multiple light receiving devices are provided in the light reception surface of the coherent light detection unit 7; and the etching portion (the opening portion of the resist mask) can be extracted from the detection region. Then, the end point of the etching is detected based on the intensity of the coherent light of the etching portion (the opening portion of the resist mask) that is extracted.

The coherent light can be produced by utilizing the light from the plasma P that is generated in the region where the plasma P is generated. Therefore, it is not always necessary to provide the light source 21. However, considering that the intensity of the light from the plasma P fluctuates, it is favorable for the light source 21 to be provided. The light source 21 is not particularly limited; and, for example, a light source including a metal halide lamp, a halogen lamp, and the like, a light source that is capable of emitting laser light, and the like are examples of the light source 21.

In the case where laser light is used, it is favorable for laser light that is scanned to be irradiated onto the surface of the processing object W.

The control unit 41 controls the depressurization unit 3, the gas supply unit 4, the power source 45, the pressure control unit 16, the flow rate control unit 13, the light source 21, and the like.

The control unit 41 extracts the etching portion (the opening portion of the resist mask) from the detection region based on the electrical signals from the light receiving devices provided in the coherent light detection unit 7. Then, the end point of the etching is detected based on the intensity of the coherent light of the etching portion (the opening portion of the resist mask) that is extracted. In other words, the control unit 41 extracts the etching portion (the opening portion of the resist mask) from a detection region having a prescribed size and detects the end point of the etching based on the intensity of the coherent light of the etching portion (the opening portion of the resist mask). Details relating to the extraction of the etching portion (the opening portion of the resist mask) and the detection of the end point of the etching are similar to those described above and are therefore omitted.

Operations of the plasma etching apparatus 40 and a plasma etching method according to this embodiment will now be illustrated.

First, the processing object W (e.g., a semiconductor wafer, a glass substrate, and the like) is transferred into the processing container 42 by a not-illustrated transfer apparatus and is placed and held on the lower electrode 48.

Then, the interior of the processing container 42 is depressurized to a prescribed pressure by the depressurization unit 3. At this time, the pressure inside the processing container 42 is adjusted by the pressure control unit 16.

Continuing, plasma products including neutral active species are produced by the plasma generation unit 43. Namely, first, a prescribed amount of the process gas G (e.g., CF₄ and the like) is supplied from the gas supply unit 4 via the flow rate control unit 13 to the region inside the processing container 42 where the plasma P is generated.

On the other hand, high frequency power of about 100 KHz to 100 MHz is applied to the lower electrode 48 by the power source unit 44. Then, because the lower electrode 48 and the upper electrode 49 form parallel-plate electrodes, discharge occurs between the electrodes to generate the plasma P. Plasma products such as neutral active species, ions, electrons, and the like are produced by the process gas G being excited and activated by the plasma P that is generated. The plasma products that are produced descend through the processing container 42 to reach the surface of the processing object W; and the etching is performed.

In such a case, of the electrons and the ions that are produced, the electrons which have little mass move rapidly to quickly reach the lower electrode 48 and the upper electrode 49. The movement of the electrons that reach the lower electrode 48 is obstructed by the blocking capacitor 46; and these electrons charge the lower electrode 48. Although the charge voltage of the lower electrode 48 reaches about 400 V to 1000 V, this is called “cathode fall.” On the other hand, because the upper electrode 49 is grounded, the movement of the electrons that reach the upper electrode 49 is not obstructed; and the upper electrode 49 substantially is not charged.

Then, physical etching (anisotropic etching) is performed by the ions moving in the lower electrode 48 (the processing object W) direction along the vertical electric field occurring due to the cathode fall to be incident on the surface of the processing object W. The neutral active species descend due to the gas flow and gravity to reach the surface of the processing object W; and chemical etching (isotropic etching) is performed.

Then, the end point of the etching is detected.

First, as described above, the intensity of the coherent light due to the light reflected at the surface of the film to be etched and the light reflected at the interface between the film to be etched and the foundation is detected by the coherent light detection unit 7. In such a case, the electrical signal from the coherent light detection unit 7 is sent to the control unit 41; and the intensity of the coherent light is detected for each of the pixels (the light receiving devices). Then, the etching portion (the opening portion of the resist mask) is extracted from the difference of the intensities of the coherent light.

Then, the point in time when the etching ends, i.e., the end point of the etching, is detected by using the portion for which the fluctuation amount of the intensity of the coherent light is the largest as the detection object, detecting the period of the intensity change of the coherent light of this portion, and calculating the film thickness from the correlation between the period, the wavelength of the light, and the refractive index and the film thickness of the film to be etched.

When detecting the end point of the etching, light can be irradiated from the light source 21 toward the detection object portion. In such a case, the coherent light also can be produced by utilizing the light from the plasma P that is generated in the region where the plasma P is generated. However, considering that the intensity of the light from the plasma P fluctuates, it is favorable for the light to be irradiated from the light source 21 toward the detection object portion.

In the case where it is determined by the control unit 41 that the etching has ended, the production of the plasma products by the plasma generation unit 43 is stopped.

The processing object W for which the etching has ended is transferred out of the processing container 42 by a not-illustrated transfer apparatus. Subsequently, if necessary, the etching described above is repeated.

As illustrated above, the plasma etching method according to this embodiment is a plasma etching method that generates the plasma P in an atmosphere depressurized below atmospheric pressure, produces the plasma products by exciting the process gas G supplied toward the plasma P, and uses the plasma products that are produced to perform etching of the processing object W, where the plasma etching method includes: a process of detecting coherent light from the processing object W by using the coherent light detection unit 7 including multiple light receiving devices in a light reception surface; and a process of detecting the end point of the etching based on the intensity of the coherent light of an etching portion (an opening portion of the resist mask) by extracting the etching portion (the opening portion of the resist mask) from the detection region 7a having a prescribed size.

Similarly to that described above, the process of detecting the end point of the etching also can include using a region having a large fluctuation amount of the intensity of the coherent light as the detection object and detecting the end point of the etching based on the average of the intensity of the coherent light of this region.

According to this embodiment, the detection object (the etching portion) can be designated because the coherent light detection unit 7 that includes the multiple light receiving devices is provided and because the etching portion (the opening portion of the resist mask) is extracted from the detection region 7a having the prescribed size. Therefore, the effect of the resist portion (the non-etching portion) of the resist mask can be suppressed. Also, effects such as noise and the like can be reduced. The designation of the detection object (the positional alignment of the detection) can be easy even in the case where the etching portion (the opening portion of the resist mask) is minute. Therefore, the detection precision of the end point of the etching can be increased.

Effects such as noise and the like can be reduced further if a region having a large fluctuation amount of the intensity of the coherent light is used as the detection object and the end point of the etching is detected based on the average of the intensity of the coherent light of this region.

Further, higher productivity, yield, quality, and the like can be realized.

Hereinabove, these embodiments are illustrated. However, the invention is not limited to these descriptions.

Appropriate design modifications made by one skilled in the art in regard to the embodiments described above also are within the scope of the invention to the extent that the features of the invention are included.

For example, the configurations, the dimensions, the material properties, the dispositions, and the like of the components included in the plasma etching apparatus 1, the plasma etching apparatus 30, and the plasma etching apparatus 40 are not limited to those illustrated and may be modified appropriately.

Although microwave excitation-type and capacitively coupled-type plasma etching apparatuses are described as examples, the generation method of the plasma is not limited thereto and may be modified appropriately. Further, the components included in the embodiments described above can be combined within the extent of feasibility; and such combinations are included in the scope of the invention to the extent that the features of the invention are included.

### EXPLANATION OF REFERENCE

1 plasma etching apparatus
2 plasma generation unit
3 depressurization unit
4 gas supply unit
5 microwave production unit
6 processing container
7 coherent light detection unit
8 control unit
9 discharge tube
10 introduction waveguide tube
14 transport tube
15 placement unit
16 interposed pressure control unit
19 detection window
19a detection window
30 plasma etching apparatus
31 plasma generation unit
32 processing container
33 control unit
34 transmissive window
35 introduction waveguide tube
40 plasma etching apparatus
41 control unit
42 processing container
43 plasma generation unit
44 power source unit
45 power source
46 blocking capacitor
48 lower electrode
49 upper electrode
M microwaves
P plasma
W processing object

1. A plasma etching apparatus, comprising:
a processing container capable of maintaining an atmosphere depressurized below atmospheric pressure;
a depressurization unit configured to depressurize an interior of the processing container to a prescribed pressure;
a placement unit provided in the interior of the processing container, the placement unit being configured to place a processing object;
a discharge tube provided at a position isolated from the processing container, the discharge tube having a region in an interior of the discharge tube used to generate plasma;
an introduction waveguide tube configured to cause microwaves radiated from a microwave production unit to propagate to introduce the microwaves to the region used to generate the plasma;
a gas supply unit configured to supply a process gas to the region used to generate the plasma;
a transport tube configured to link the discharge tube to the processing container;
a detection window provided in a wall surface of the processing container, the detection window being configured to transmit light;
a coherent light detection unit including a plurality of light receiving devices in a light reception surface configured to receive coherent light emitted from a surface of a processing object placed in the placement unit; and
a control unit configured to detect an end point of etching based on an output from the coherent light detection unit,
the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

2. A plasma etching apparatus, comprising:
a processing container capable of maintaining an atmosphere depressurized below atmospheric pressure, the processing container having a region in an interior of the processing container used to generate plasma;
a depressurization unit configured to depressurize the interior of the processing container to a prescribed pressure;
a placement unit provided in the interior of the processing container, the placement unit being configured to place a processing object;
a plasma generation unit configured to generate the plasma by supplying electromagnetic energy to the region used to generate the plasma;
a gas supply unit configured to supply a process gas to the region used to generate the plasma;
a detection window provided in a wall surface of the processing container, the detection window being configured to transmit light;
a coherent light detection unit including a plurality of light receiving devices in a light reception surface configured to receive coherent light emitted from a surface of a processing object placed in the placement unit; and
a control unit configured to detect an end point of etching based on an output from the coherent light detection unit,
the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

3. A plasma etching apparatus, comprising:
a processing container capable of maintaining an atmosphere depressurized below atmospheric pressure;
a depressurization unit configured to depressurize an interior of the processing container to a prescribed pressure;
a placement unit provided in the interior of the processing container, the placement unit being configured to place a processing object;
a discharge tube provided at a position isolated from the processing container, the discharge tube having a region in an interior of the discharge tube used to generate plasma;
an introduction waveguide tube configured to cause microwaves radiated from a microwave production unit to propagate to introduce the microwaves to the region used to generate the plasma;
a gas supply unit configured to supply a process gas to the region used to generate the plasma;
a transport tube configured to link the discharge tube to the processing container;
a detection window provided in a wall surface of the processing container, the detection window being configured to transmit light;
a light source configured to irradiate light via the detection window onto a surface of a processing object placed in the placement unit;
a coherent light detection unit including a plurality of light receiving devices in a light reception surface configured to receive coherent light emitted from the surface of the processing object placed in the placement unit; and
a control unit configured to detect an end point of etching based on an output from the coherent light detection unit,
the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

4. A plasma etching apparatus, comprising:
a processing container capable of maintaining an atmosphere depressurized below atmospheric pressure, the processing container having a region in an interior of the processing container used to generate plasma;
a depressurization unit configured to depressurize the interior of the processing container to a prescribed pressure;
a placement unit provided in the interior of the processing container, the placement unit being configured to place a processing object;
a plasma generation unit configured to generate the plasma by supplying electromagnetic energy to the region used to generate the plasma;
a gas supply unit configured to supply a process gas to the region used to generate the plasma;
a detection window provided in a wall surface of the processing container, the detection window being configured to transmit light;
a light source configured to irradiate light via the detection window onto a surface of a processing object placed in the placement unit;
a coherent light detection unit including a plurality of light receiving devices in a light reception surface configured to receive coherent light emitted from the surface of the processing object placed in the placement unit; and
a control unit configured to detect an end point of etching based on an output from the coherent light detection unit,
the control unit being configured to use an output from the light receiving devices of a detection region of the coherent light detection unit to extract an output of the light receiving device of a portion of the detection region corresponding to an etching portion to detect the end point of the etching based on an intensity of the coherent light determined from the output of the light receiving device of the portion of the detection region corresponding to the etching portion.

5. The plasma etching apparatus according to claim 1, wherein the control unit is configured to use a region having a large fluctuation amount of the intensity of the coherent light as a detection object to detect the end point of the etching based on an average of the intensity of the coherent light of the region.

6. The plasma etching apparatus according to claim 2, wherein the control unit is configured to use a region having a large fluctuation amount of the intensity of the coherent light as a detection object to detect the end point of the etching based on an average of the intensity of the coherent light of the region.

7. The plasma etching apparatus according to claim 3, wherein the control unit is configured to use a region having a large fluctuation amount of the intensity of the coherent light as a detection object to detect the end point of the etching based on an average of the intensity of the coherent light of the region.

8. The plasma etching apparatus according to claim 4, wherein the control unit is configured to use a region having a large fluctuation amount of the intensity of the coherent light as a detection object to detect the end point of the etching based on an average of the intensity of the coherent light of the region.

9. A plasma etching method configured to generate plasma in an atmosphere depressurized below atmospheric pressure, produce plasma products by exciting a process gas supplied toward the plasma, and use the plasma products to perform etching of a processing object, the plasma etching method comprising:
detecting coherent light from the processing object by using a coherent light detection unit including a plurality of light receiving devices in a light reception surface; and
detecting an end point of etching based on an intensity of the coherent light by using an output from the light receiving devices of a detection region of the coherent light detection unit to extract an output of the light receiving device of a portion of the detection region corresponding to an etching portion, the intensity of the coherent light being determined from the output of the light receiving device of the portion of the detection region corresponding to the etching portion.

10. The plasma etching method according to claim 9, wherein the detecting of the end point of the etching includes using a region having a large fluctuation amount of the intensity of the coherent light as a detection object to detect the end point of the etching based on an average of the intensity of the coherent light of the region.
